(19) United States
(12) Patent Application Publication
(10) Pub. No.: US 2026/0255566 A1
(43) Pub. Date: Aug. 27, 2026

(54) SRAM INTEGRATION WITH SHIFTED STACKED FETS

(71) Applicant: INTERNATIONAL BUSINESS MACHINES CORPORATION, Armonk, NY (US)

(72) Inventors: Tsung-Sheng Kang, Ballston Lake, NY (US); Ruilong Xie, Niskayuna, NY (US); Tao Li, Slingerlands, NY (US); Chen Zhang, Santa Clara, CA (US); Tenko Yamashita, Schenectady, NY (US); Shay Reboh, Guilderland, NY (US)

(21) Appl. No.: 19/061,150

(22) Filed: Feb. 24, 2025

(51) Int. Cl. H10B 10/00; H10D 30/00; H10D 30/01; H10D 30/67; H10D 62/10; H10D 84/01; H10D 84/83

(52) U.S. Cl. CPC H10B 10/12; H10D 30/0191; H10D 30/502; H10D 30/6735; H10D 62/118; H10D 84/0149; H10D 84/833

(57) ABSTRACT

A semiconductor device includes a first field effect transistor (FET) on a first level and a second FET on a second level stacked over and overlapping the first FET of the first level in an overlap region. The source/drain (S/D) regions of the second FET are shifted relative to S/D regions of the first FET. A merged gate connection connects gates of the first FET and the second FET in the overlap region.

### BACKGROUND

The present invention generally relates to semiconductor devices and processing methods, and more particularly to stacked field effect transistors (FETs) shifted between stacked layers and integrated within a static random access memory (SRAM) integration process.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

An electrical constraint arises when attempting to connect to source/drain regions on different stack levels. Areal space is needed for contacts that bypass one level and connect to another level. The areal space for the contacts needs to account for adequate conduction of the contact and adequate dielectric protection around the contacts to prevent short circuits. In addition, areal space needs to be conserved in different portions of a device. For example, in logic regions as well as memory regions. As such, a method is needed to seamlessly incorporate different device structures within a single integration scheme while minimizing consumed layout area.

### SUMMARY

In accordance with an embodiment of the present invention, a semiconductor device includes a first field effect transistor (FET) on a first level and a second FET on a second level stacked over and overlapping the first FET of the first level in an overlap region. The source/drain (S/D) regions of the second FET are shifted relative to S/D regions of the first FET. A merged gate connection connects gates of the first FET and the second FET in the overlap region.

In accordance with another embodiment of the present invention, a semiconductor device, includes a first field effect transistor (FET) on a first level, and a second FET on a second level that is stacked over and overlaps the first FET of the first level in an overlap region, where source/drain (S/D) regions of the second FET are shifted relative to S/D regions of the first FET. A contact passes through the first level to connect to a source/drain (S/D) region of the second FET on the second level. A bitline contact connects to the contact on a backside of the semiconductor device which connects to a bitline.

In accordance with another embodiment of the present invention, a method of forming a semiconductor device includes forming a first field effect transistor (FET) on a first level, the first FET including a gate-all-around (GAA) device; forming a bonding layer on the first level; forming second FETs on a second level over the first level having shifted source/drain (S/D) regions of the second FET relative to S/D regions of the first FET, the second FETs including forksheet devices; forming a merged gate connection through the bonding layer to connect gates of the first FET and a second FET; forming a contact through the bonding layer to connect to the shifted S/D regions through the first level; and forming bitline contacts to connect bitlines on the first level to the shifted S/D regions using the contact.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures, wherein:

FIG. 1 shows cross-sectional views of a logic region and a SRAM region for a semiconductor device having a lower level fabricated with gate-all-around (GAA) devices, and having placeholders formed through lower source/drain (S/D) regions, in accordance with an embodiment of the present invention;

FIG. 2 shows cross-sectional views of the logic region and the SRAM region for the semiconductor device having a nanosheet bonded to the lower level, in accordance with an embodiment of the present invention;

FIG. 3 shows cross-sectional views of the logic region and the SRAM region for the semiconductor device having the nanosheet patterned to form different types of field effect transistors, in accordance with an embodiment of the present invention;

FIG. 4 shows cross-sectional views of the logic region and the SRAM region for the semiconductor device having dielectric bars formed between closely positioned nanosheet portions for forming forksheet devices, in accordance with an embodiment of the present invention;

FIG. 5 shows cross-sectional views of the logic region and the SRAM region for the semiconductor device having top dummy gate and top S/D regions formed, in accordance with an embodiment of the present invention;

FIG. 6 shows cross-sectional views of the logic region and the SRAM region for the semiconductor device having a dielectric layer (e.g., an interlevel dielectric layer) formed, in accordance with an embodiment of the present invention;

FIG. 7 shows cross-sectional views of the logic region and the SRAM region for the semiconductor device having replacement metal gates and gate cuts formed, in accordance with an embodiment of the present invention;

FIG. 8 shows cross-sectional views of the logic region and the SRAM region for the semiconductor device having top side middle of the line contacts formed, in accordance with an embodiment of the present invention;

FIG. 9 shows cross-sectional views of the logic region and the SRAM region for the semiconductor device having a back end of line layer and a carrier wafer applied, in accordance with an embodiment of the present invention;

FIG. 10 shows cross-sectional views of the logic region and the SRAM region for the semiconductor device having the structure flipped to process a backside and a substate removed to an etch stop layer, in accordance with an embodiment of the present invention;

FIG. 11 shows cross-sectional views of the logic region and the SRAM region for the semiconductor device having a semiconductor layer removed to expose lower S/D region and gate conductors, in accordance with an embodiment of the present invention;

FIG. 12 shows cross-sectional views of the logic region and the SRAM region for the semiconductor device having a dielectric layer formed on the backside of the semiconductor device and planarized to expose a portion of the placeholders, in accordance with an embodiment of the present invention;

FIG. 13 shows cross-sectional views of the logic region and the SRAM region for the semiconductor device having the placeholders removed to expose top S/D regions through the placeholder openings, in accordance with an embodiment of the present invention;

FIG. 14 shows cross-sectional views of the logic region and the SRAM region for the semiconductor device having the dielectric layer on the backside of the semiconductor device patterned to form contact openings, in accordance with an embodiment of the present invention;

FIG. 15 shows cross-sectional views of the logic region and the SRAM region for the semiconductor device having contacts formed in the openings and where the placeholders were removed and connected to a backside interconnect layer, in accordance with an embodiment of the present invention; and

FIG. 16 shows a cross-sectional view showing a cross-coupled connection arrangement for cross-coupling transistors of an SRAM cell, in accordance with an embodiment of the present invention.

### DETAILED DESCRIPTION

In accordance with embodiments of the present invention, devices and methods are described which include stacked field effect transistors that are shifted between levels. The shift provides enough space to enable adequate-sized contacts and provide scaling benefits that include reduced layout area. In addition, overlapping regions exist to permit gates to be connected along vertical regions where the overlapping occurs. This avoids the alignment and formation processes needed to make connections to gates while conserving layout area.

In an embodiment, logic and memory portions of a semiconductor device can be integrated into a single process sequence. By integrating the logic and memory structure processing, a more efficient and cost-effective fabrication process can result.

In some embodiments, a semiconductor device includes stacked field effect transistors (FETs) at different levels of the semiconductor device. The FETs can include gate-all-around (GAA) gate structures, forksheet structures or other FET structures. In an embodiment, a semiconductor device includes, e.g., at least one forksheet device formed over at least one GAA device in another level. The at least one forksheet device can include two forksheet devices where channels of the two forksheet devices are separated by a dielectric bar. A bonding layer (e.g., an oxide) can be formed between a top and a bottom device in the stack. For example, the GAA device on a bottom level can include a forksheet device over the GAA device on a top level. Channels of bottom GAA devices can be offset (e.g., not centered) with respect to the two forksheet devices on top level. The GAA device can be overlapped (vertically offset) with one of the two forksheet devices more than the other.

In another embodiment, a semiconductor device includes stacked FETs at different levels of the semiconductor device. The FETs can include gate-all-around (GAA) gate structures, forksheet structures or other FET structures. In an embodiment, a semiconductor device includes, e.g., at least one forksheet device formed over at least one GAA device in another level. A channel width (shown in the plane of the page) of the at least one forksheet device can be wider than a channel width of the GAA device. A critical dimension (CD) of the dielectric bar can be less than a CD of a gate cut (CT) between bottom devices (e.g., two adjacent GAA FETs).

In another embodiment, a semiconductor device includes a forksheet device having a pass-gate, and an adjacent forksheet device with a pull-down gate are isolated by a dielectric bar therebetween on a top level. The forksheet devices are over a pull-up FET on a bottom level. The pull-down gate and the pull-up gate are connected by a gate connector between levels (e.g., through the bonding layer). The semiconductor device can include a bit-line connected to a top source drain region (S/D) by a backside contact, and a supply voltage line (e.g., VDD on a backside of the semiconductor device) that is connected to a bottom S/D by another backside contact.

In an embodiment, on a logic side of the semiconductor device, a GAA device can be stacked over another GAA device for a complementary metal oxide semiconductor (CMOS) cell, with top a diffusion region (RX or S/D) shifted with respect to bottom RX. On a memory side (e.g., a static random access memory (SRAM) side), forksheet devices can be stacked over a GAA device for a two N-region, one P-region cell (2N1P cell), with a pull-down device that overlaps with a bottom RX, and a pass-gate device shifted away from bottom RX. A first merged supply voltage (e.g., VSS) contact and a second merged supply voltage (e.g., VDD) contact can be employed. The first and the second merged supply contacts can connect to respective supply lines on opposite sides of the semiconductor device (e.g., one on top, one on the bottom). Wordlines and node lines can be separated by forksheet dielectric bars.

In other embodiments, methods for forming a semiconductor device include forming bottom layer devices with a backside contact placeholder for top devices. A top channel layer (e.g., a nanosheet) is bonded over the bottom level. The top channel layer is patterned to form top RXs, and dielectric bars are formed, such that pull-down devices are over pull-up devices, and pass-gate devices are shifted relative to the pull-up devices, over a backside contact placeholder.

Top or frontside replacement metal gates (RMG) are formed such that pull-up and pull-down gates are connected by a gate connector through the bonding layer or other dielectric between the levels. Top or frontside interconnects, such as, e.g., VSS are formed on the frontside. Backside interconnects are formed by removing the backside contact placeholder, such that bitlines and VDD are formed on the bottom or backside.

In other embodiments, a frontside deep contact can extend through the first stacked level to connect with the second stacked level. A backside deep contact can extend through the second stacked level to connect with the first stacked level.

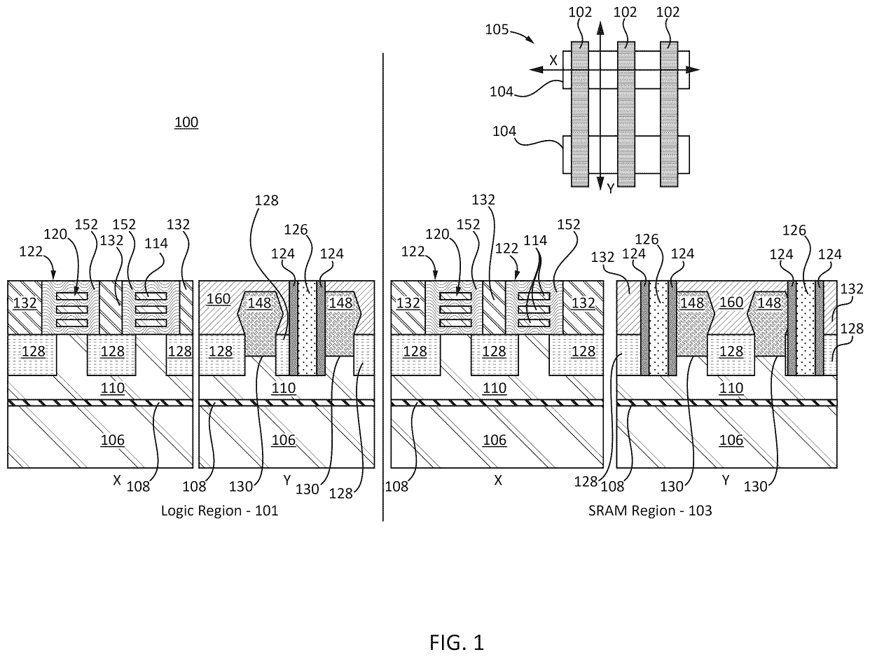

Referring now to the drawings in which like numerals represent the same or similar elements and initially to FIG. 1, devices and methods for manufacturing a stacked field effect transistor (FET) device are shown in accordance with embodiments of the present invention. A wafer 100 includes a substrate 106 on which the stacked FET device will be fabricated.

FIG. 1 depicts two orthogonal views X and Y taken at corresponding sections X and Y in inset 105. Inset 105 shows gate lines 102 and active region lines 104 for reference. Corresponding X and Y views are depicted throughout FIGS. Active region lines 104 represent S/D regions for transistor devices to be formed, and gate lines 102 are represented for such transistor devices. Transistor channels are formed on the active region lines 104 below the gate lines 102. In addition, two different regions of the wafer 100 are depicted. Namely, a logic region 101 and an SRAM region 103. Each region includes its own corresponding X and Y views which are also depicted throughout FIGS.

The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In an embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc.

A layer stack or stacks are applied to or formed on the semiconductor layer 110 to form bottom level FETs. In an embodiment, one or more nanosheets (NS) are applied to the semiconductor layer 110. In another embodiment, the layer stacks can be epitaxially grown using different chemistries to form layers having different properties. In an embodiment, a layer stack 120 includes alternating semiconductor layers. Each of semiconductor layers are selectively removeable relative to the other, e.g., by a selective etching process. In an embodiment, one semiconductor layer (sacrificial layer) includes SiGe, where Ge is greater than about 30 atomic % of the compound; and the other semiconductor layer (semiconductor layer 114) can be employed to form FET channels. Semiconductor layer 114 can include, e.g., Si. It should be understood that other materials or atomic percentages can be employed for semiconductor layers. In other embodiments, different stack orders and numbers may be employed for semiconductor layers.

The stack 120 can be patterned to expose and etch the semiconductor layer 110. In an embodiment, a hard mask (not shown) may be formed by blanket depositing a layer of hard mask material, providing a patterned photoresist (not shown) on top of the layer of hard mask material, and then etching the layer of hard mask material to provide the hard mask pattern for etching the stack 120 and a portion of the semiconductor layer 110. The patterned photoresist can be produced by applying a blanket photoresist layer to the surface of the hard mask and exposing the photoresist layer to a pattern of radiation and then developing the pattern into the photoresist layer utilizing resist developer. The pattern in the photoresist layer is transferred to the hard mask by an etch process.

Openings are formed through stack 120, e.g., by using an anisotropic etch process, such as a reactive ion etch (RIE) or an ion beam etch (IBE). Semiconductor layer 110 is further etched to form trenches therein in accordance with the openings. Shallow trench isolation (STI) or STI 128 is formed in the etched trenches. STI 128 can be formed by depositing dielectric material, such as, e.g., SiO₂, SiOₓN_{y}, SiCO or other suitable compounds. STI 128 can be deposited using chemical vapor deposition (CVD), although other deposition methods can be employed. The STI 128 can then be etched, e.g., by RIE, to a top level of the semiconductor layer 110.

Processing continues with the formation of a dummy gate structures (not shown), gate spacers, and inner spacers. A dummy gate material can include a polysilicon, amorphous Si or other selectively removeable material. The dummy gate material is deposited followed by a hard mask material. The hard mask material is patterned to form a hard mask. The hard mask is employed to etch the dummy gates. Then, a deposition process is employed to form gate spacers. Gate spacers can include an oxide, such as silicon dioxide, although other dielectric materials can be employed. The hard mask and spacers can be employed as an etch mask to recess stack 120 to expose and recess the semiconductor layer 110 as shown in Y sections.

Inner spacers (not shown) are formed and include a dielectric material. The inner spacers are formed by recessing the SiGe semiconductor layers and filling the recess with dielectric material. The inner spacers can include an oxide, such as silicon dioxide, although other dielectric materials can be employed. The remaining portions of the SiGe semiconductor layers are removed.

An epitaxial growth process is performed to form bottom source/drain (S/D) regions 148. Bottom S/D regions 148 are employed for bottom transistors of the stacked FET device under construction. Bottom S/D regions 148 can include Si or SiGe and include faceted surfaces when epitaxial growth is not confined. The bottom S/D regions 148 are grown from exposed portions 130 of the semiconductor layer 110.

In an embodiment, the bottom S/D regions 148 can be designated as either P-type or N-type devices. The N-type devices can include Si, and P-type devices can include SiGe. The bottom S/D regions 148 can be appropriately doped during formation by epitaxial growth. For example, the bottom S/D regions 148 can be doped by introducing p dopants (e.g., B, Ga, etc.) during epitaxial formation. Similarly, the bottom S/D regions 148 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device type during processing of the other.

A dielectric layer 160, such as, e.g., an interlevel dielectric layer (ILD) is formed on the wafer 100. The dielectric layer 160 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, although other deposition methods can be employed. The dielectric layer 160 can be planarized using e.g., chemical mechanical polishing (CMP).

Processing continues with the removal of the dummy gate material and forming of gate conductor 152 in a replacement metal gate (RMG) process for a bottom stack level of the wafer 100 to form gates structures 122 (e.g., High-K Metal Gates (HKMGs)).

A mask (not shown) is formed and patterned to etch through the dielectric layer 160 and a portion of the S/D regions 148 to expose the semiconductor layer 110 for the frontside of the wafer 100. A deposition process is employed to form spacers 124. Spacers 124 can include an oxide, such as silicon dioxide, although other dielectric materials can be employed. The deposition process can include a CVD, although other methods can be employed. The deposition is followed by a spacer etch to remove material from horizontal surfaces to complete the spacers 124 and expose the semiconductor layer 110. Placeholders 126 are formed by epitaxial growth using a crystalline structure of the semiconductor layer 110 to initiate crystal growth. The placeholders 126 can include, e.g., SiGe or other material that can be selectively etched relative to the semiconductor layer 110.

A gate cut process can be performed to shape the gate structures 122. A gate cut etch can include a patterned etch to cut the gate structures 122. The gate cut is then filled with a dielectric material (e.g., an oxide) and the surface planarized to form gate cuts (CT) 132.

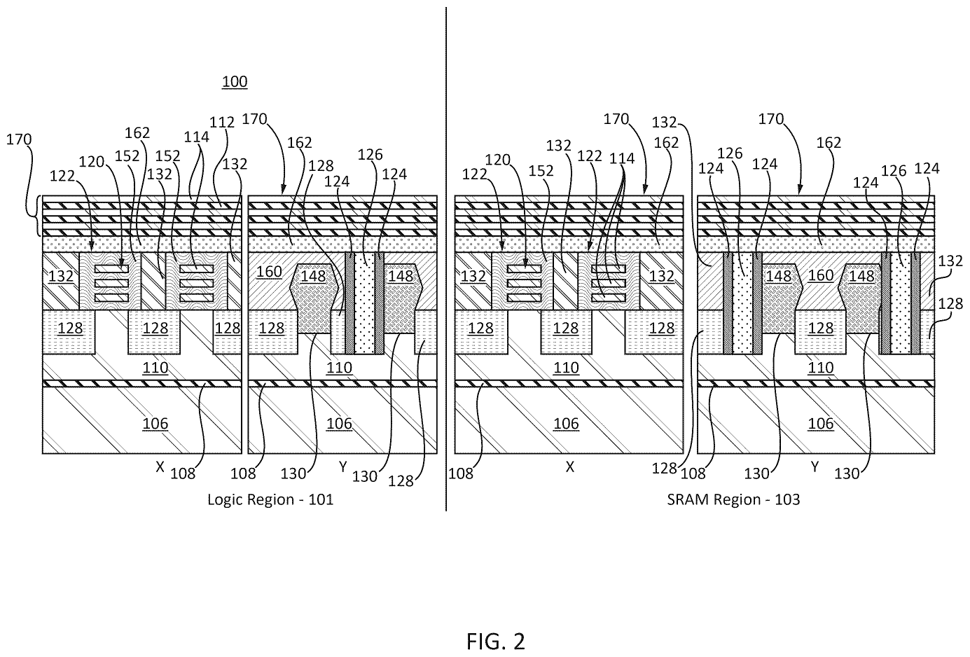

Referring to FIG. 2, a nanosheet 170 or stack can be bonded with a bonding layer 162 to facilitate the formation of a next level of stacked transistor structures. The bonding process can include applying the bonding layer 162 with the nanosheet 170 or stack on the wafer 100. The bonding layer 162 can include materials such as silicon dioxide, silicon oxynitride, or other suitable dielectric materials.

The bonding layer 162 can be subjected to thermal annealing to strengthen the bond between the bonding layer 162 and the wafer 100. The nanosheet 170 or stack includes semiconductor layers 112, 114, which will be employed in forming top FETs. In an embodiment, semiconductor layers 112 include SiGe, where Ge is greater than about 30 atomic % of the compound; and the semiconductor layers 114 can be employed to form FET channels. Semiconductor layer 114 can include, e.g., Si. It should be understood that other materials or atomic percentages can be employed for semiconductor layers. In other embodiments, different stack orders and numbers may be employed for semiconductor layers.

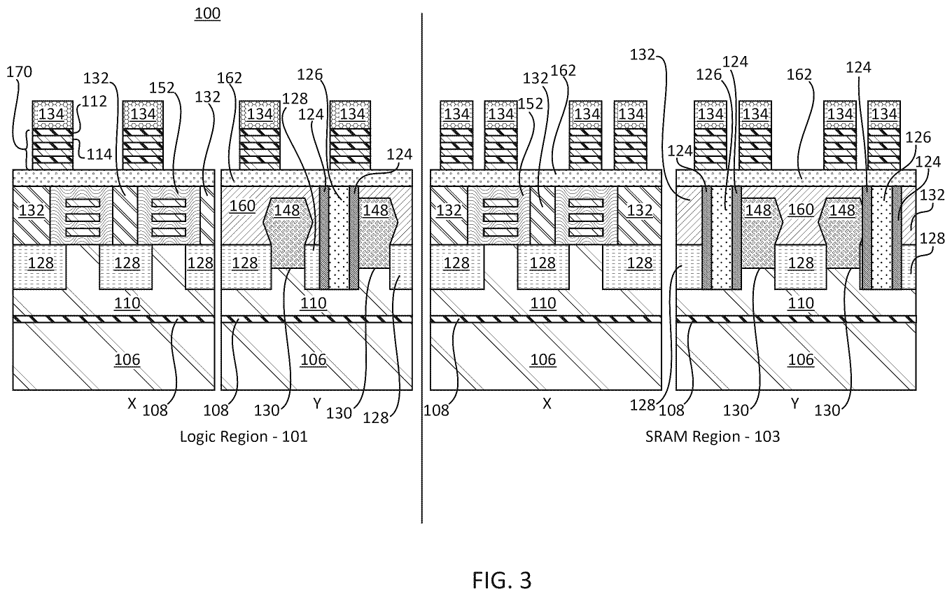

Referring to FIG. 3, the nanosheet 170 is patterned and etched using a suitable photolithographic patterning process. A hard mask layer is deposited over the nanosheet 170 and patterned using, e.g., photolithography to form a hard mask 134. The size and shape of the patterned structures of the hard mask 134 can depend on the type or types of FETs to be formed. For example, in the SRAM regions 103, the hard mask 134 can provide shapes for etching the nanosheet 170 that can be employed to form, e.g., GAA and/or forksheet devices. The nanosheet 170 is then etched in accordance with the hard mask 134.

It should be understood that while the nanosheet 170 can be patterned in accordance with the structures in a level below, the nanosheet 170 can include active region structures patterned to provide an offset relative to the underlying device in a bottom layer.

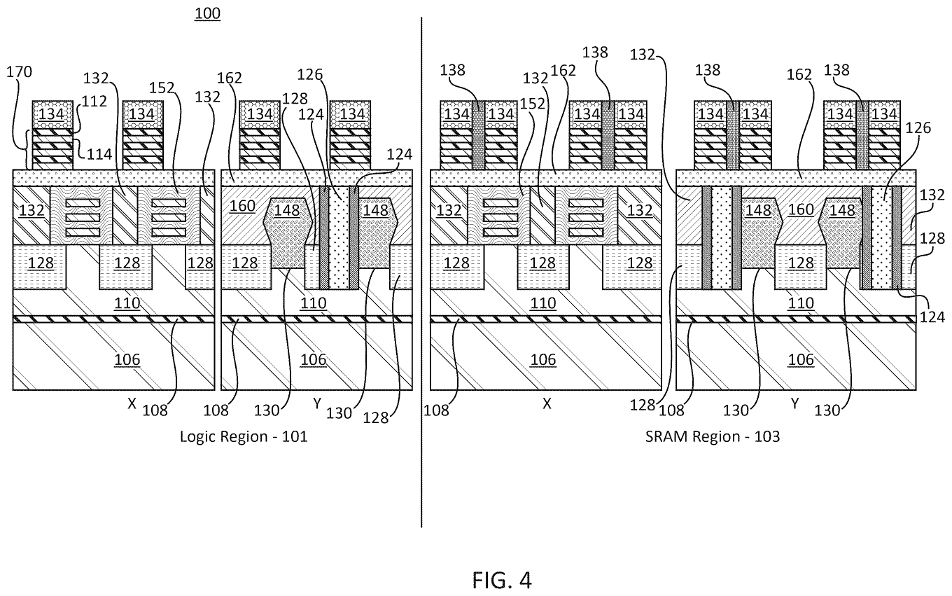

Referring to FIG. 4, dielectric bars 138 are formed in the SRAM region 103. The dielectric bars 138 can be formed by a conformal liner deposition process followed by an isotropic etch, e.g., a wet etch. The isotropic etch removes dielectric material that was deposited in larger spaces while leaving material in tighter spaces. In this way, active region portions formed from the nanosheet 170 that are closer to one another have dielectric bars 138 remaining therebetween. The material for the dielectric bars 138 can include, e.g., SiCN although materials can be employed.

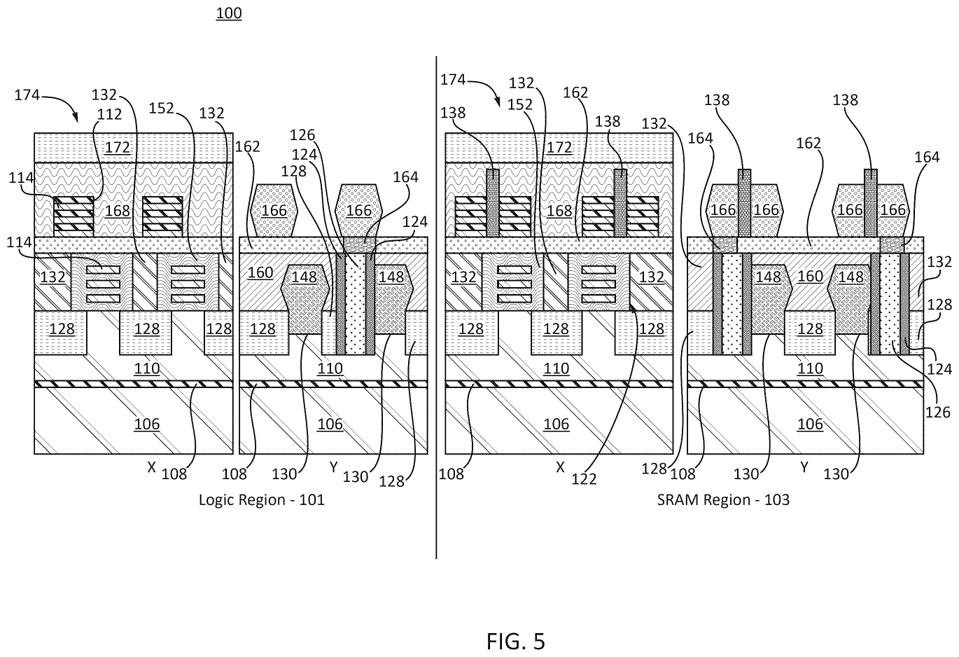

Referring to FIG. 5, as before, dummy gate structures (not shown) are formed for the top level. This includes the deposition and patterning of dummy gate materials, gate spacer formation and nanosheet recessing. Processing continues with the removal of the hard mask 134 and the formation of dummy gate structures, gate spacers, and inner spacers. A dummy gate material 168 can include a polysilicon, amorphous Si or other selectively removeable material. The dummy gate material 168 is deposited followed by a hard mask material 172. The hard mask material 172 is patterned to form a hard mask. The hard mask is employed to etch dummy gates 174. Then, a deposition process is employed to form gate spacers (not shown). Gate spacers can include an oxide, such as silicon dioxide, although other dielectric materials can be employed. The hard mask and spacers can be employed as an etch mask to recess the nanosheet 170 and expose the bonding layer 162 in active regions, as shown in Y sections.

Inner spacers (not shown) are formed and include a dielectric material. The inner spacers are formed by recessing the semiconductor layers 112 and filling the recess with dielectric material. The inner spacers can include an oxide, such as silicon dioxide, although other dielectric materials can be employed.

Exposed portions of the bonding layer 162 can be patterned and etched to provide openings through the bonding layer 162 to expose the placeholder 126 in a lower level or layers. By exposing the placeholders 126 an epitaxial growth process can be performed to initiate growth of second placeholders 164 which can also be employed to form top S/D regions 166 (RX) on an upper level.

An epitaxial growth process is performed to form the second placeholders 164 through the bonding layer 162. A same or different epitaxial growth process can be employed to form the top S/D regions 166. The top S/D regions 166 are employed for top transistors of the stacked FET device under construction. Top S/D regions 166 can include Si or SiGe and include faceted surfaces when epitaxial growth is not confined. The top S/D regions 166 are grown from exposed portions of the second placeholders 164. Note that the top S/D regions 166 can be offset or shifted relative to the bottom S/D regions 148.

In an embodiment, the top S/D regions 166 can be designated as either P-type or N-type devices. The N-type devices can include Si, and P-type devices can include SiGe. The top S/D regions 166 can be appropriately doped during formation by epitaxial growth. For example, the top S/D regions 166 can be doped by introducing p dopants (e.g., B, Ga, etc.) during epitaxial formation. Similarly, the top S/D regions 166 can be doped by introducing n dopants (e.g., P, As, etc.) during epitaxial formation.

In one particularly useful embodiment, the bottom S/D regions 148 can be P-type and the top S/D regions 166 can be N-type. This can result in a 2N1P cell, or a single cell with three transistors, e.g., three transistors that occupy a single cell, for example, two FETs which can include forksheet FETs on an upper level and a GAA FET on a lower level. Other configurations are also contemplated. In other embodiments, P-type and N-type devices can be formed adjacent to one another. Processing would include forming one device type and then the other device type by employing block masks to protect each device type during processing of the other. Note that some top S/D regions 166 can have epitaxial growth initiated using placeholders 164 that are not depicted as they are not aligned with the given cross-section.

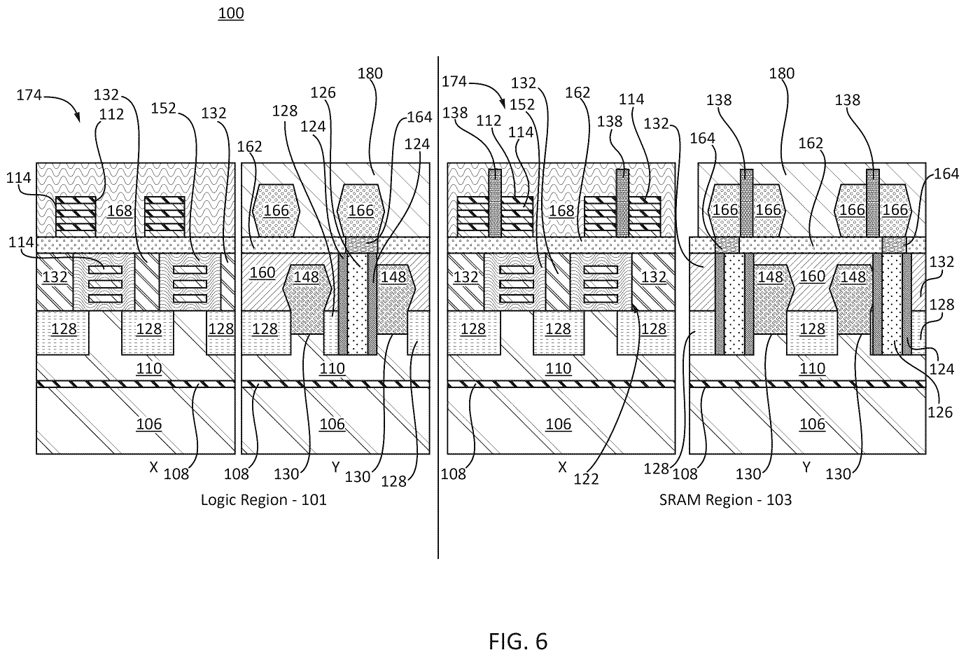

Referring to FIG. 6, the hard mask material 172 is removed and a dielectric layer 180, such as, e.g., an interlevel dielectric layer (ILD) is formed on the wafer 100. The dielectric layer 180 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The dielectric layer 160 can be deposited using CVD, although other deposition methods can be employed. The dielectric layer 180 can be planarized using e.g., CMP.

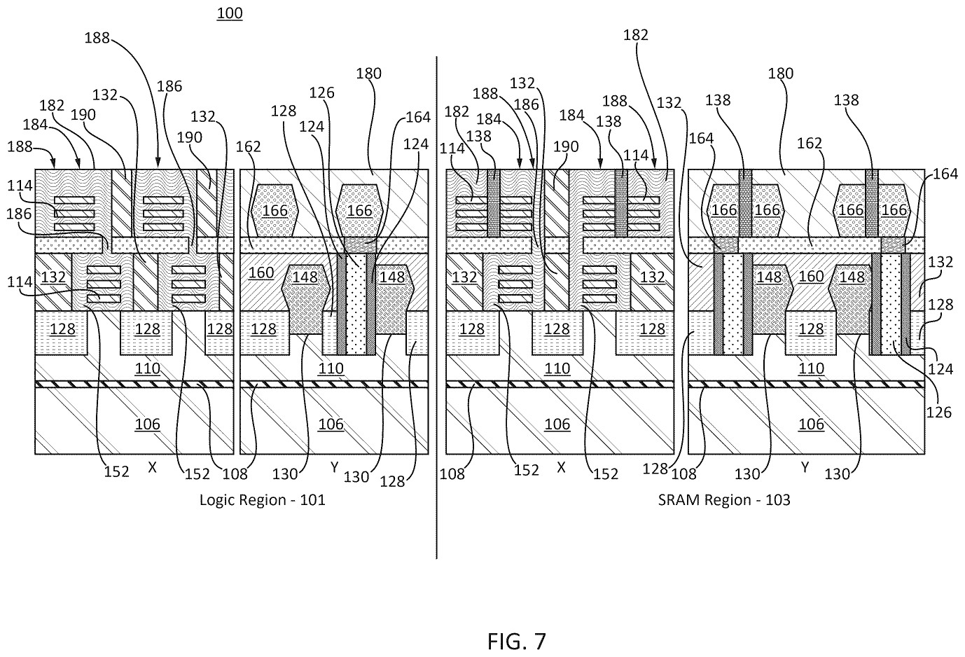

Referring to FIG. 7, the dummy gate material 168 is removed. The semiconductor layers 112 are removed. A dielectric material (not shown), such as a high-dielectric constant material is formed over the semiconductor layers 114 (transistor channels). A sacrificial dielectric material (not shown) is formed where the dummy gate material was removed from. The sacrificial dielectric material is patterned and etched to expose portions of the bonding layer 162 and to form gate merge openings through the bonding layer 162. The gate merge openings can be formed in the logic region 101 and/or the SRAM region 103 is a single process, although multiple processes can also be employed. An etch process, e.g., RIE, is performed to etch through the bonding layer 162 to expose the gate conductors 152 on the bottom level.

A gate conductor 182 is formed in a replacement metal gate (RMG) process for a top stack level of the wafer 100 to form gate structures 184 (e.g., HKMGs) and concurrently form gate merge connections 186.

Replacement metal gate structures 188 are formed after removal of the dummy gate material 168. The replacement metal gate structures 188 may include the high-k dielectric layer (not shown) deposited on semiconductor channel regions (semiconductor layers 114). The high-k dielectric layer may include materials such as hafnium oxide, zirconium oxide, or other metal oxides with a dielectric constant higher than silicon dioxide.

The replacement metal gate structures 188 can include a work function metal layer that may be deposited on the high-k dielectric layer. The work function metal may be selected based on the desired threshold voltage for the transistor. For N-type devices, metals such as titanium nitride, tantalum nitride, or aluminum may be used. For P-type devices, metals like titanium nitride with added aluminum, or platinum may be employed.

Following the work function metal, a low resistance metal fill may be deposited to complete the gate structure 188 and form gate conductors 182 or electrodes. The gate merge connections 186 can include the work function metal and/or the low resistance metal. The low resistance metal fill may include materials such as tungsten, aluminum, or copper. The low resistance metal fill may be deposited using techniques such as, e.g., CVD or ALD. In some cases, multiple work function metal layers may be used to fine-tune the work function. Additionally, barrier layers or adhesion layers may also be incorporated between the various metal layers to improve interface quality and prevent inter-diffusion of materials. It should be understood that the gate structures 122 can include similar or different materials and processing than the gate structures 188.

A gate cut process can be performed to shape the gate structures 188. A gate cut etch can include a patterned etch to cut the gate structures 188. The gate cut is then filled with a dielectric material (e.g., an oxide) and the surface planarized to from gate cuts (CT) 190.

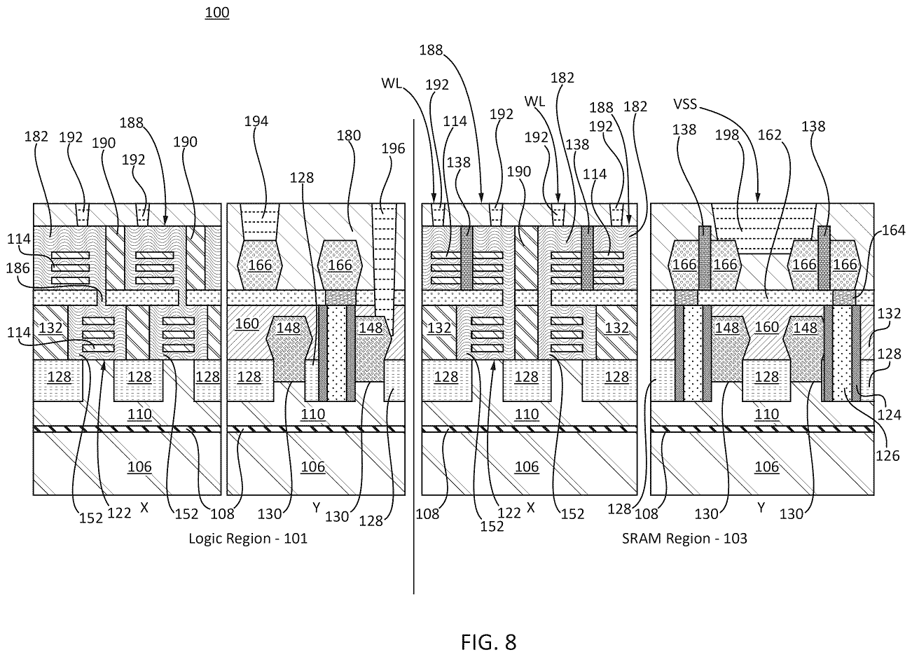

Referring to FIG. 8, contacts 192, 194, 196 and 198 are formed to respectively make connections with the gate conductors 182, the top S/D regions 166 from a top side of the wafer 100, the bottom S/D regions 148 from a top side of the wafer 100 and between the top S/D regions 166. For contacts 192, 194, 196 and 198, trenches or holes are formed through the dielectric layer 180. The trenches or holes expose the underlying materials for the gate structures 188, bottom S/D regions 148 and/or top S/D regions 166. Contacts 196 can include deep contacts that extend through the dielectric layer 180, the bonding layer 162 and into the dielectric layer 160 to connect to the bottom S/D regions 148. Note that the deep contacts 196 and each of contacts 192, 194 and 198 can be formed in same or different patterning process and metal fill process.

In some embodiments, a silicide liner, such as Ti, Ni, NiPt can be deposited in the trenches or holes for S/D regions before a conductive fill, then a diffusion barrier can be formed in the trenches prior to the conductive fill. The diffusion barrier can include, e.g., TiN, TaN, or similar materials. The diffusion barrier can be employed with or without the silicide layer.

A conductive fill is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, plasma enhanced CVD (PECVD), ALD or any other suitable deposition method. The conductive fill is planarized, e.g., by CMP, to form contacts 192, 194, 196 and 198. As mentioned, the contacts 192, 194, 196 and 198 can be formed concurrently or in separate processes. The contact 198 can join or connect top S/D regions 166 to a supply voltage line (e.g., VSS) to be formed. In an embodiment, the contact 198 can form the supply voltage line. The contact 196 connects to a bottom S/D region 148 from a frontside of the wafer 100. The contacts 192 can include node contacts and/or word lines contacts. In an example, some of the contacts 192 can include word line contacts (WL). In an embodiment, the contacts 192 can form the word lines or form the word lines with connected gate conductors.

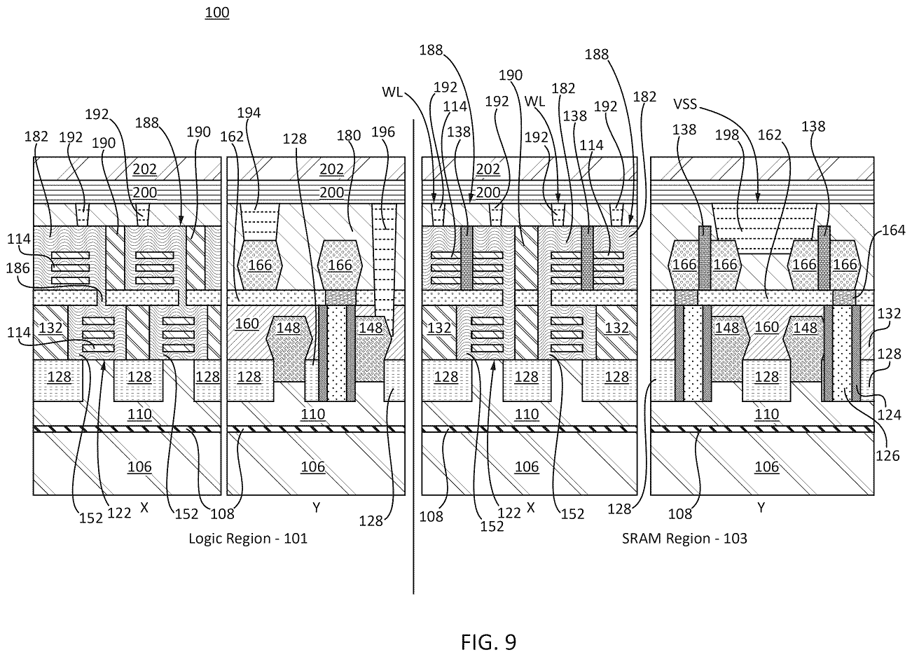

Referring to FIG. 9, a back end of the line (BEOL) layer 200, which can include metal structures and dielectric layers to complete the top or front side of the stacked FET device and provide electrical access to the devices formed. The BEOL layer 200 can include power lines (e.g., VSS) and other metal structures to make on-chip and off-chip connections. A carrier wafer 202 can be bonded to the BEOL layer 200. The carrier wafer 202 provides support and transportability to the wafer 100 for further processing which includes flipping the wafer 100 and removing portions of a bottom side of the stacked FET device.

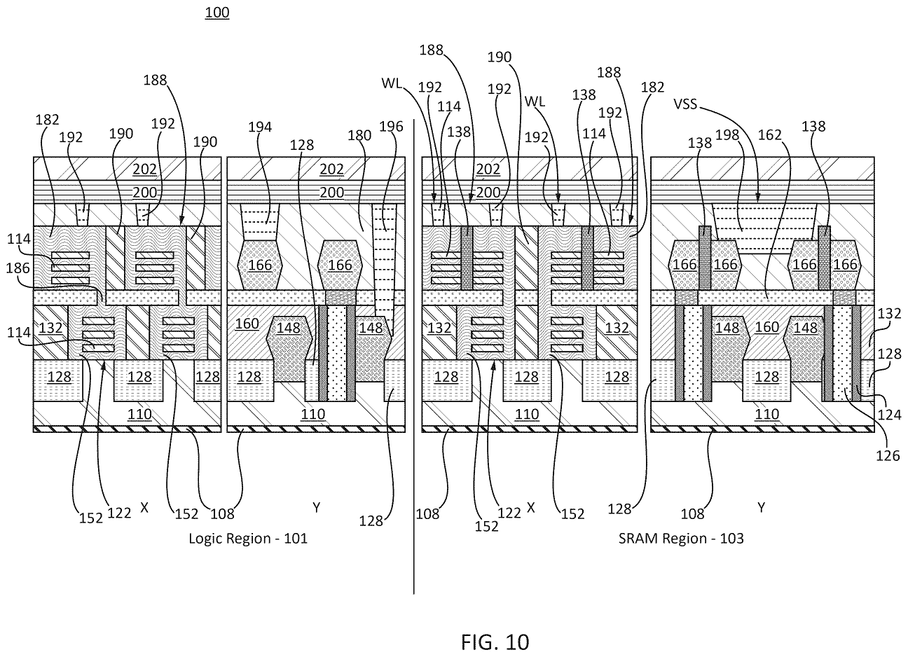

Referring to FIG. 10, to continue processing, the wafer 100 can be flipped to process features on the backside of the stacked FET device. However, for clarity and consistency, the stacked FET device will be shown in the FIGS. in a same orientation as previously described with continued and consistent reference to bottom/top, back/front. The substrate 106 is removed from the bottom side of the stacked FET device. The substrate 106 can be removed by an etch process that stops on the etch stop layer 108.

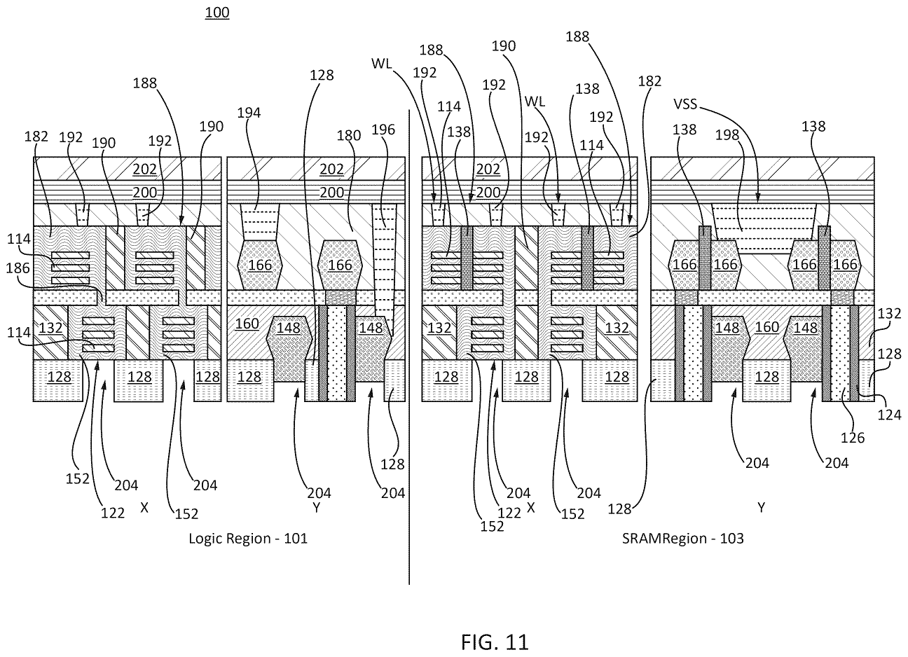

Referring to FIG. 11, the etch stop layer 108 is then removed by an etch process. In an alternate embodiment, a CMP process can be employed. With the removal of the etch stop layer 108, the semiconductor layer 110 is exposed. The semiconductor layer 110 is removed by an etch process that selectively removes the material of the semiconductor layer 110 relative to the STI 128, the bottom S/D regions 148, placeholders 126 and the gate structures 122. The etch process creates openings 204 to permit access to the gate conductors 152 and bottom S/D regions 148 from a bottom or backside of the wafer 100.

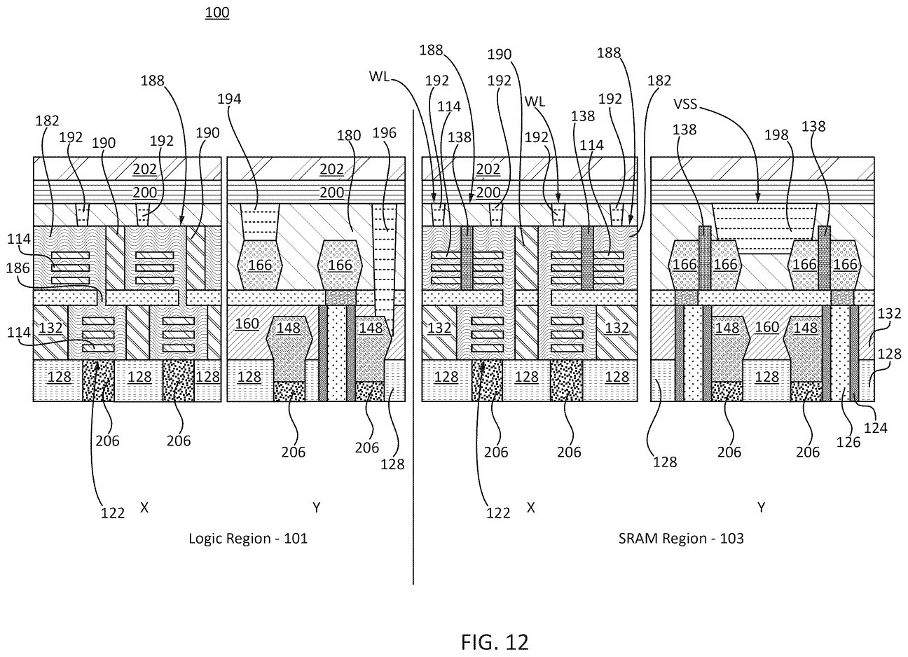

Referring to FIG. 12, a dielectric layer 206 is formed over the STI 128, the bottom S/D regions 148 and other regions on a backside of the wafer 100. The dielectric layer 206 includes a material that is selectively removeable relative to the STI 128, the bottom S/D regions 148 and the placeholders 126 (and spacers 124). The dielectric layer 206 can include a similar material and formation process as that of dielectric layer 160 or dielectric layer 180. A planarization process (e.g., CMP) is performed to level off a free surface of the dielectric layer 206 and expose the placeholders 126.

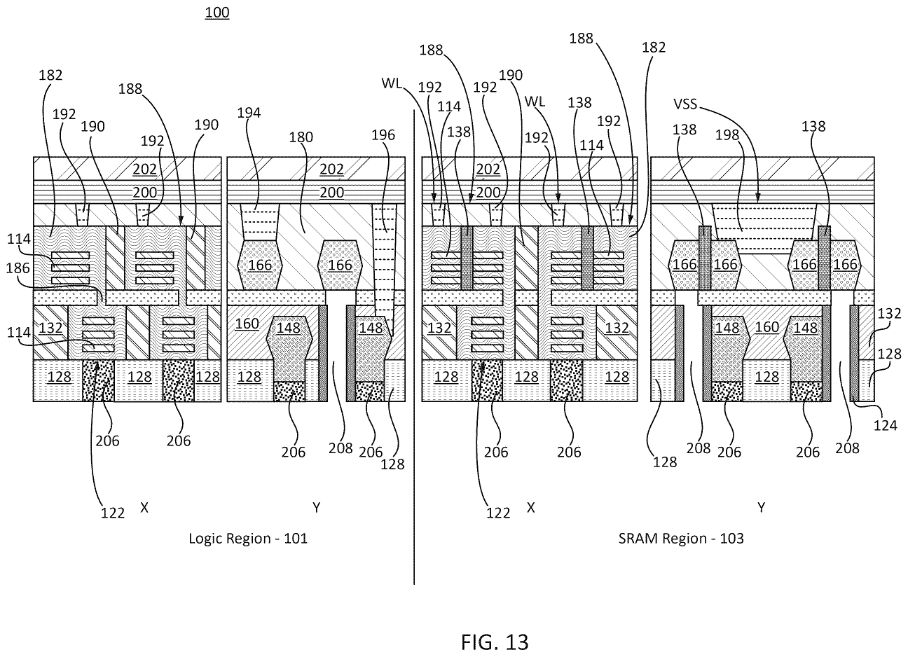

Referring to FIG. 13, the placeholders 126, which were exposed by the planarization process are removed by an etching process. The etching process can continue to further remove the second placeholders 164 to expose top S/D regions 166 through openings 208 formed by removing the placeholders 126 and the second placeholders 164. The etch process removes the material of the placeholders 126 and the second placeholders 164 relative to surrounding dielectric materials, (e.g., STI 128, dielectric layer 206, dielectric layer 180 and bonding layer 162). The etch can include a wet or dry etch.

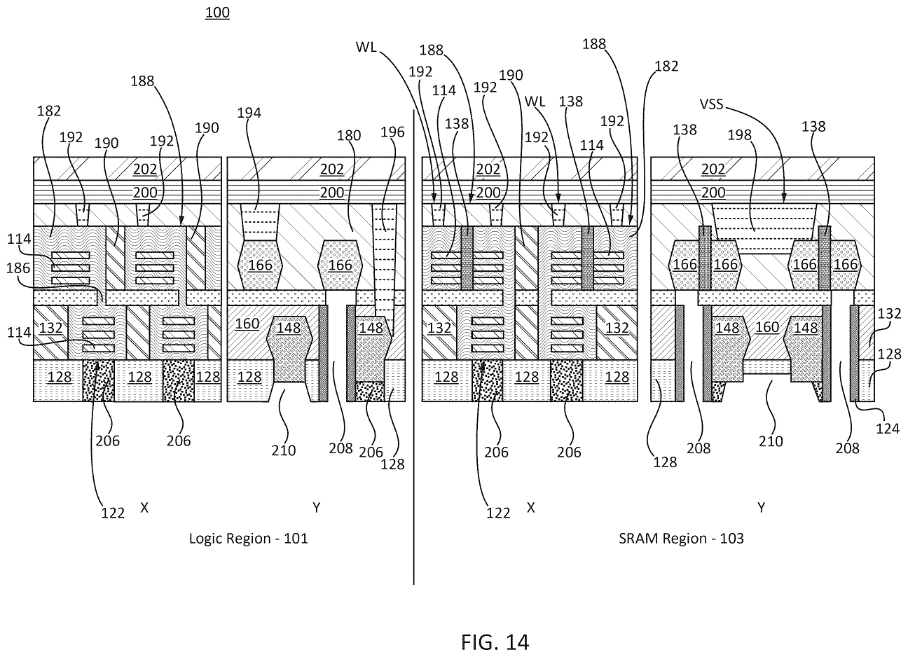

Referring to FIG. 14, backside contact patterning is performed to make connections with the bottom S/D regions 148 directly from a backside of the wafer 100 and to make contact with top S/D regions 166 from a bottom level of the stacked device. Patterning can be performed using photolithographic patterning techniques to create an etch mask to etch the trenches or holes with an anisotropic etch., e.g., RIE. The trenches or holes expose the underlying bottom S/D regions 148 for direct contacts. A patterned mask (not shown) is formed on the backside of the wafer 100, and openings 210 are formed by etching in accordance with the etch mask. Some openings 210 can access multiple components, e.g., multiple S/D regions 148.

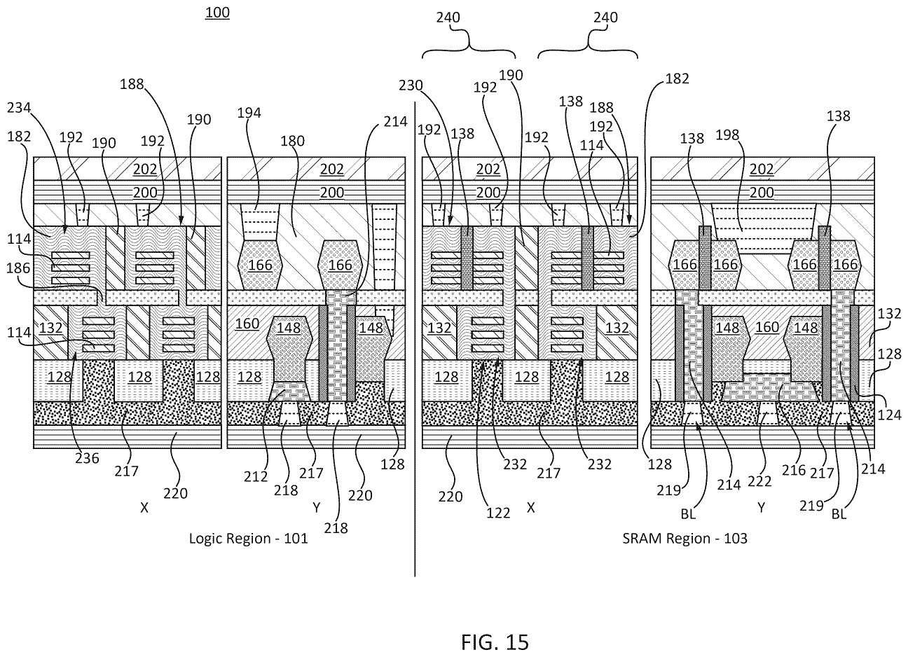

Referring to FIG. 15, contacts 212, 214 and 216 are formed in openings 210 and 208. Contacts 212 connect to the bottom S/D regions 148. Contacts 214 connect to the top S/D regions 166. Contacts 216 connect between bottom S/D regions 148.

In some embodiments, a silicide liner, such as Ti, Ni, NiPt can be deposited in the trenches or holes for S/D regions before a conductive fill, then a diffusion barrier can be formed in the trenches prior to the conductive fill. The diffusion barrier can include, e.g., TiN, TaN, or similar materials. The diffusion barrier can be employed with or without the silicide layer.

A conductive fill is performed to fill the trenches and holes. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the contacts 212, 214 and 216 on the backside of the wafer 100. The contacts 212, 214 and 216 can be formed concurrently or in separate processes. In some embodiments, the contacts 216 can join or connect two adjacent (same level) S/D regions. Using the backside of the wafer 100 can provide additional layout space, which can further permit larger sized contacts.

A dielectric layer 217 is formed to support the formation of additional backside metal structures. The dielectric layer 217 is patterned by using photolithographic patterning techniques to create an etch mask to etch openings with an anisotropic etch, e.g., RIE. The openings expose the underlying contacts 212, 214 and 216.

Diffusion barriers and/or silicide liners can be formed in the openings. A conductive fill is performed to fill the trenches and holes. The conductive fill can include materials, such as, e.g., Cu, Ru, Mo, Rh, W, Ir, and alloys or combinations of these and other conductive materials. The conductive fill can be formed using a deposition method, such as, e.g., CVD, PECVD, ALD or any other suitable deposition method. The conductive fill is planarized, e.g., by CMP, to form the contacts 218, bitlines or bitline contacts 219 (to connect to bitlines (BL)) and/or power rail contacts 222 (e.g., to connect to VDD) from the backside of the wafer 100. In an embodiment, the power rail contacts 222 can include a power rail for a positive supply voltage (e.g., VDD) or a negative supply voltage (e.g., VSS). In an embodiment, the power rail contacts 222 can connect to VDD on a backside (while VSS is disposed on a frontside of the wafer 100) or vice versa. Other configurations for the power rails are also contemplated, e.g., power rails can include a same supply voltage potential on opposite side of the device or be reversed.

A backside interconnect layer 220 is formed on and connects with the power rail contacts 222, bitline contacts 218 and contacts 218. The backside interconnect layer 220 can include metal structures and dielectric layers to complete the bottom side of the stacked FET device and provide electrical access to the FET devices formed.

In accordance with embodiments of the present invention, different types of devices can be integrated into different regions of the semiconductor device fabricated on the wafer 100. For example, in some embodiments, a semiconductor device includes stacked FETs and different levels of the semiconductor device can include GAA devices 232, forksheet devices 230 or other FET structures within the SRAM region 103 and/or the logic region 101. Devices on a same level between the SRAM region 103 and the logic region 101 can have different FET devices integrated within a same processing sequence.

By employing forksheet devices 230 in accordance with an embodiment, device density per cell 240 can be increased to save layout area. Forksheet devices 230 can be separated by dielectric bars 138. The bonding layer 162 can separate the GAA device 232 on the bottom level from the forksheet device 230 on the top level. Channels of bottom GAA device 232 can be offset with respect to the forksheet device(s) 230 on the top level. The GAA device 232 can be overlapped (vertically offset) with one of the two forksheet devices 230 more than the other. Gate conductors of the GAA device 232 and the forksheet device 230 can be merged by connecting the gates using the gate merge connection 186.

The shifts or offsets permit wiring access to the S/D regions 148 and 166 from a top and bottom of the device. Further, employing forksheet devices 230 is especially beneficial in SRAM devices where 6, 8 or 10 transistors (FETs) can be employed for each memory cell. For example, a 6T SRAM cell, as depicted in the SRAM region 103 of FIG. 15 can employ 4 NFETs (top) and 2 PFETs (bottom). In the example structure, 2 PFETs (GAA devices 232) can be employed on a first level and 4 NFETs (e.g., forksheet devices 230) can be employed on a second level for the 6T SRAM cell. In an embodiment, at least one forksheet device 230 can be formed over at least one GAA device 232 in another level.

Further, GAA devices 234 and 236 can be integrated into a same logic region 101 and forksheet devices in SRAM region 103 can be fabricated concurrently with GAA devices 234 in the logic region 101 in a same integration scheme.

As a result of the shift in S/D regions and gate structures, a channel width of the forksheet device 230 can be wider than a channel width of the GAA device 232. Further, a critical dimension (CD) of the dielectric bar 138 can be less than a CD of the gate cut (CT) 132 between bottom devices (e.g., two adjacent GAA FETs) or less than a CD of the gate cut (CT) 190 between top devices (e.g., between forksheet pairs).

In an embodiment, on the memory side (e.g., SRAM region 103), the forksheet device 230 can be stacked over the GAA device 232 to form a cell 240 having two N-regions, one P-region cell (2N1P cell). A merged supply voltage (e.g., VSS) contact 198 and a merged supply voltage (e.g., VDD) contact 216 can be employed. Wordline contacts and node line contacts 192 can be separated by forksheet dielectric bars 138.

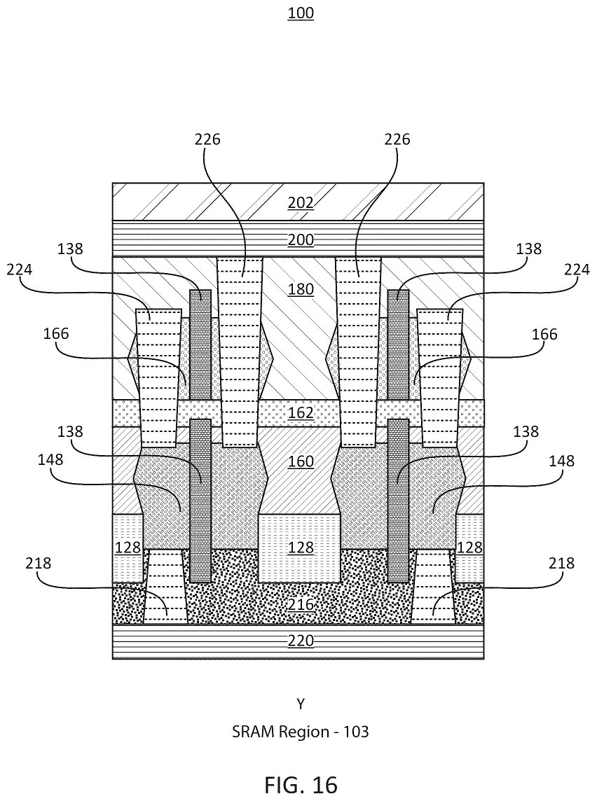

Referring to FIG. 16, a cross-sectional view of the SRAM region 103 shows another configuration for implementation cross-coupled FETs in an SRAM cell. The shifting of S/D regions 148 and 166 permits area conserving structures to be achieved. Internal and external contacts interconnects can be fabricated to conserve layout area. For example, internal contacts 224, running within the top S/D regions 166, are formed to make connections between the top S/D regions 166 and bottom S/D regions 148. In addition, contacts 226 connect other top S/D regions 166 with bottom S/D regions 148. With these connections a frontside and backside cross-couple arrangement can be achieved, for an SRAM memory cell. The frontside cross-coupled inputs can connect at contacts 226 while the backside cross-couple can connect at contacts 218.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or backside interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment,” as well as other variations thereof, means that a particular feature, structure, characteristic, and so forth described in connection with the embodiment is included in at least one embodiment. Thus, the appearances of the phrase “in one embodiment” or “in an embodiment,” as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent, by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first field effect transistor (FET) on a first level;
a second FET on a second level stacked over and overlapping the first FET of the first level in an overlap region, where source/drain (S/D) regions of the second FET are shifted relative to S/D regions of the first FET; and
a merged gate connection connecting gates of the first FET and the second FET in the overlap region.

2. The semiconductor device of claim 1, wherein the first FET includes a gate-all-around (GAA) device and the second FET includes a forksheet device.

3. The semiconductor device of claim 1, further comprising a contact connected through one level to connect to a S/D region on another level.

4. The semiconductor device of claim 1, wherein the second FET includes two FETs having a dielectric bar therebetween.

5. The semiconductor device of claim 4, wherein the two FETs include forksheet FETs and the two FETs and the first FET occupy a single cell.

6. The semiconductor device of claim 1, wherein a channel width of the second FET is wider than a channel width of the first FET.

7. The semiconductor device of claim 1, further comprising a bonding layer between the first level and the second level.

8. The semiconductor device of claim 7, wherein the merged gate connection extends through the bonding layer.

9. The semiconductor device of claim 1, further comprising a logic region and a memory region, the logic region including FETs on the first level and the second level which are different than FETs in the memory region on a same level.

10. A semiconductor device, comprising:
a first field effect transistor (FET) on a first level;
a second FET on a second level stacked over and overlapping the first FET of the first level in an overlap region, where source/drain (S/D) regions of the second FET are shifted relative to S/D regions of the first FET;
a contact passing through the first level to connect to a source/drain (S/D) region of the second FET on the second level; and
a bitline contact connected to the contact on a backside of the semiconductor device which connects to a bitline.

11. The semiconductor device of claim 10, wherein the first FET includes a gate-all-around (GAA) device and the second FET includes a forksheet device.

12. The semiconductor device of claim 10, wherein the second FET includes two FETs having a dielectric bar therebetween.

13. The semiconductor device of claim 12, wherein the two FETs include forksheet FETs and the two FETs and the first FET occupy a single cell.

14. The semiconductor device of claim 10, wherein a channel width of the second FET is wider than a channel width of the first FET.

15. The semiconductor device of claim 10, further comprising a bonding layer between the first level and the second level.

16. The semiconductor device of claim 15, wherein a merged gate connection extends through the bonding layer to connect gates of the first FET and the second FET.

17. The semiconductor device of claim 15, wherein the contact passes through the bonding layer.

18. The semiconductor device of claim 10, further comprising a logic region and a memory region, the logic region including FETs on the first level and the second level which are different than FETs in the memory region on a same level.

19. A method of forming a semiconductor device, comprising:
forming a first field effect transistor (FET) on a first level, the first FET including a gate-all-around (GAA) device;
forming a bonding layer on the first level;
forming second FETs on a second level over the first level having shifted source/drain (S/D) regions of the second FET relative to S/D regions of the first FET, the second FETs including forksheet devices;
forming a merged gate connection through the bonding layer to connect gates of the first FET and the second FET;
forming a contact through the bonding layer to connect to the shifted S/D regions through the first level; and
forming bitline contacts to connect bitlines on the first level to the shifted S/D regions using the contact.

20. The method as recited in claim 19, wherein the second FETs include two forksheet FETs having a dielectric bar therebetween, wherein the two FETs and the first FET occupy a single cell.
